(19) United States
(12) Patent Application Publication
(10) Pub. No.: US 2024/0333225 A1
(43) Pub. Date: Oct. 3, 2024

(54) DOHERTY AMPLIFIER CIRCUIT

(71) Applicant: Murata Manufacturing Co., Ltd., Kyoto (JP)

(72) Inventor: Shohei IMAI, Kyoto (JP)

(21) Appl. No.: 18/610,639

(22) Filed: Mar. 20, 2024

(30) Foreign Application Priority Data
Mar. 31, 2023 (JP) 2023-057286

(51) Int. Cl. H03F 1/02; H03F 3/193; H03F 3/21

(52) U.S. Cl. CPC H03F 1/0288; H03F 3/193; H03F 3/211; H03F 2200/451

(57) ABSTRACT

A Doherty amplifier circuit includes a carrier amplifier that amplifies a high frequency signal, a peak amplifier that amplifies the high frequency signal, and a control circuit that controls the peak amplifier based on a supply current of an amplifying transistor in the carrier amplifier.

### CROSS REFERENCE TO RELATED APPLICATION

This application claims priority from Japanese Patent Application No. 2023-057286 filed on Mar. 31, 2023. The content of this application is incorporated herein by reference in its entirety.

### BACKGROUND ART

The present disclosure relates to a Doherty amplifier circuit.

A Doherty amplifier circuit is known as a high efficiency power amplifier circuit. The Doherty amplifier circuit is generally configured such that a carrier amplifier that operates regardless of the power level of an input signal and a peak amplifier that is turned off when the power level of the input signal is low and is turned on when the power level is high are connected in parallel. In this configuration, when the power level of the high frequency input signal is high, the carrier amplifier operates while maintaining saturation at the saturation output power level. As a result, the Doherty amplifier circuit can improve efficiency as compared with a normal power amplifier circuit.

The following United States Patent Application, Publication No. 2016/0241209, United States Patent Application, Publication No. 2020/0028472, and Japanese Unexamined Patent Application Publication No. 2019-041277 describe techniques for controlling the bias of a peak amplifier.

The technique described in United States Patent Application, Publication No. 2016/0241209 detects the saturation of the carrier amplifier with the bias circuit of the carrier amplifier interposed therebetween, and controls the bias circuit of the peak amplifier depending on the detection signal.

The technique described in United States Patent Application, Publication No. 2020/0028472 detects the saturation of the carrier amplifier by the output signal of the carrier amplifier, and controls the bias circuit of the peak amplifier depending on the detection signal.

The technique described in Japanese Unexamined Patent Application Publication No. 2019-041277 controls the bias circuit of the peak amplifier depending on the high frequency input signal level input to the Doherty amplifier circuit or the high frequency input signal level input to the carrier amplifier.

### BRIEF SUMMARY

In the techniques described in United States Patent Application, Publication No. 2016/0241209 and United States Patent Application, Publication No. 2020/0028472, the circuit for detecting the saturation of the carrier amplifier requires a response time of approximately several tens of nanoseconds. Therefore, the following inconveniences may occur. For example, when a high frequency input signal having an instantaneous (a time much shorter than several tens of nanoseconds) increase in power is input to the Doherty amplifier circuit, during the period of several tens of nanoseconds from the start of saturation in the carrier amplifier until the bias point of the peak amplifier fluctuates, there may be a period of time during which the carrier amplifier is saturated. This may result in an inability to maintain high quality of the high frequency output signal in the Doherty amplifier circuit. In addition, when the Doherty amplifier circuit is applied to a communication device, it may result in an inability to maintain high communication quality.

Although the technique described in Japanese Unexamined Patent Application Publication No. 2019-041277 operates depending on the high frequency input signal level, the high frequency input signal level is detected with the bias circuit, and it is considered that the response speed is generally slow. Consequently, it is conceivable that it may result in an inability to maintain high quality of the high frequency output signal in the Doherty amplifier circuit.

The present disclosure suppresses a decrease in quality of a high frequency output signal.

A Doherty amplifier circuit of one aspect of the present disclosure includes: a carrier amplifier that amplifies a high frequency signal; a peak amplifier that amplifies the high frequency signal; and a control circuit that controls the peak amplifier based on a supply current of an amplifying transistor in the carrier amplifier.

According to the present disclosure, it is possible to suppress a decrease in quality of the high frequency output signal.

### BRIEF DESCRIPTION OF THE DRAWINGS

FIG. 1 is a diagram showing a configuration of a Doherty amplifier circuit of a first embodiment.

FIG. 2 is a diagram showing a first specific example of a circuit configuration of a current monitoring circuit and an operation circuit of the Doherty amplifier circuit of the first embodiment.

FIG. 3 is a diagram showing a second specific example of a circuit configuration of a current monitoring circuit and an operation circuit of the Doherty amplifier circuit of the first embodiment.

FIG. 4 is a diagram showing a configuration of a Doherty amplifier circuit of a second embodiment.

FIG. 5 is a diagram showing a configuration of a drive level detection circuit of the Doherty amplifier circuit of the second embodiment.

FIG. 6 is a diagram showing a first specific example of a circuit configuration of an operation circuit of the Doherty amplifier circuit of the second embodiment.

FIG. 7 is a diagram showing a second specific example of a circuit configuration of an operation circuit of the Doherty amplifier circuit of the second embodiment.

### DETAILED DESCRIPTION

Hereinafter, embodiments of the present disclosure will be described in detail with reference to the drawings. The present disclosure is not limited by the embodiments. Each embodiment is an example, and it goes without necessarily saying that partial substitution or combination of the configurations shown in different embodiments is possible. In a second embodiment and subsequent embodiments, descriptions about matters common to a first embodiment will be omitted, and only different points will be described. Particularly, the same operation and effect due to the same configuration will not be repeatedly mentioned for each embodiment.

### First Embodiment

### Overall Configuration

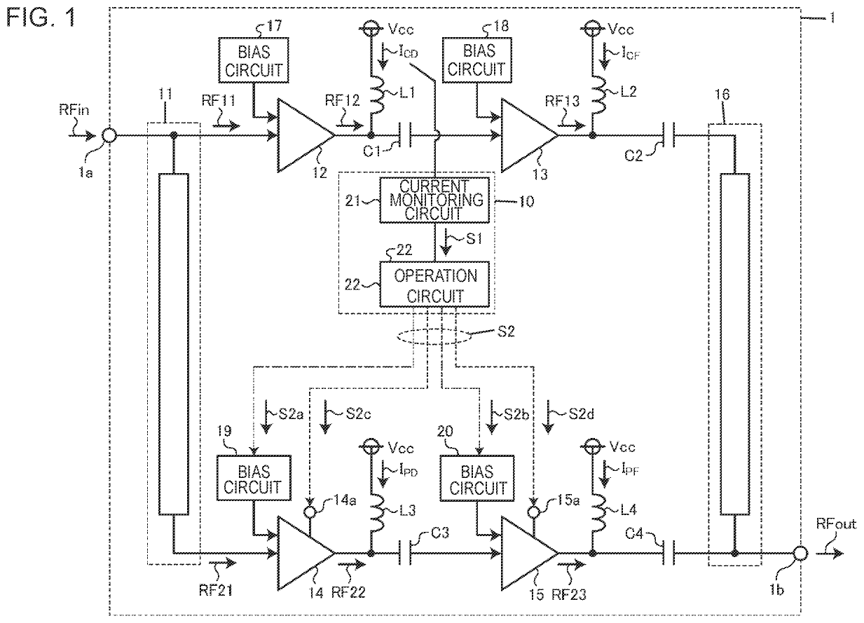

FIG. 1 is a diagram showing a configuration of a Doherty amplifier circuit of a first embodiment. A Doherty amplifier circuit 1 amplifies a high frequency signal RFin input to an input terminal 1a and outputs a high frequency signal RFout from an output terminal 1b.

The Doherty amplifier circuit 1 includes a control circuit 10, a distributor 11, a first stage (driver stage) carrier amplifier 12, a final stage (power state) carrier amplifier 13, a first stage peak amplifier 14, a final stage peak amplifier 15, a synthesizer 16, and bias circuit 17 to bias circuit 20. The control circuit 10 includes a current monitoring circuit 21 and an operation circuit 22.

In the embodiment, the number of stages of the Doherty amplifier circuit 1 is set to two, but the present disclosure is not limited thereto. The number of stages of the Doherty amplifier circuit 1 may be one stage or may be three or more stages.

In the embodiment, each of the carrier amplifier 12, the carrier amplifier 13, the peak amplifier 14, and the peak amplifier 15 is a single-ended amplifier, but the present disclosure is not limited thereto. Each of the carrier amplifier 12, the carrier amplifier 13, the peak amplifier 14, and the peak amplifier 15 may be a differential amplifier.

The distributor 11 divides the high frequency signal RFin input to the input terminal 1a into high frequency signals RF11 and RF21 having phases that are approximately 90° different from each other, outputs the high frequency signal RF11 to the carrier amplifier 12, and outputs the high frequency signal RF21 to the peak amplifier 14. The “approximately 90°” includes not only a 90° phase but also a 90°±45° phase.

The phase of the high frequency signal RF21 is exemplified to be delayed by 90° from the high frequency signal RF11. The power of the high frequency signal RF11 and the power of the high frequency signal RF21 are exemplified to be the same.

The bias circuit 17 applies a bias to the carrier amplifier 12. The collector or drain of the amplifying transistor (to be described later) in the carrier amplifier 12 is electrically connected to the power supply potential Vcc with a choke coil L1 interposed therebetween. A supply current I_{CD} flows from the power supply potential Vcc to the collector or drain of the amplifying transistor with the choke coil L1 interposed therebetween. The supply current I_{CD} is a collector current when the amplifying transistor in the carrier amplifier 12 is a bipolar transistor, and is a drain current when the amplifying transistor in the carrier amplifier 12 is a field effect transistor (FET).

The carrier amplifier 12 outputs a high frequency signal RF12, which is amplified from the high frequency signal RF11, to the carrier amplifier 13 with a capacitor C1 interposed therebetween. The capacitor C1 is a DC cut capacitor that cuts a DC component of the high frequency signal RF12.

The bias circuit 18 applies a bias to the carrier amplifier 13. The collector or drain of the amplifying transistor in the carrier amplifier 13 is electrically connected to the power supply potential Vcc with a choke coil L2 interposed therebetween. A supply current I_{CF} flows from the power supply potential Vcc to the collector or drain of the amplifying transistor with the choke coil L2 interposed therebetween. The supply current I_{CF} is a collector current when the amplifying transistor in the carrier amplifier 13 is a bipolar transistor, and is a drain current when the amplifying transistor in the carrier amplifier 13 is a field effect transistor.

The carrier amplifier 13 outputs a high frequency signal RF13, which is amplified from the high frequency signal RF12, to the synthesizer 16 with a capacitor C2 interposed therebetween. The capacitor C2 is a DC cut capacitor that cuts a DC component of the high frequency signal RF13.

The current monitoring circuit 21 monitors the supply current I_{CD} and outputs a signal S1 depending on the supply current I_{CD} to the operation circuit 22.

The operation circuit 22 adds an operation to the signal S1 and outputs a signal S2. The operation circuit 22 is exemplified to output the signal S1 directly as the signal S2, for example. In addition, the operation circuit 22 is exemplified to output the signal S2 by inverting and amplifying the signal S1. However, the present disclosure is not limited thereto. The signal S2 is exemplified to include signals S2a, S2b, S2c, and S2d.

As a first specific example (to be described later), the operation circuit 22 outputs the signal S2a to the bias circuit 19 and outputs the signal S2b to the bias circuit 20. When outputting a current signal, the operation circuit 22 may respectively output separate signal S2a and signal S2b to the bias circuit 19 and the bias circuit 20, as shown in FIG. 1. When outputting a voltage signal, the operation circuit 22 may output one common signal S2 to the bias circuit 19 and the bias circuit 20.

The operation circuit 22 may output only one of the signal S2a and the signal S2b. That is, the operation circuit 22 may output the signal S2a to the bias circuit 19 and need not output the signal S2b to the bias circuit 20. Alternatively, the operation circuit 22 may output the signal S2b to the bias circuit 20 and need not output the signal S2a to the bias circuit 19.

As a second specific example (to be described later), the operation circuit 22 outputs a signal S2c to an enable terminal 14a (to be described later) of the peak amplifier 14 and outputs a signal S2d to an enable terminal 15a of the peak amplifier 15. When outputting a current signal, the operation circuit 22 may respectively output separate signal S2c and signal S2d to the enable terminal 14a of the peak amplifier 14 and the enable terminal 15a of the peak amplifier 15, as shown in FIG. 1. When outputting a voltage signal, the operation circuit 22 may output one common signal S2 to the enable terminal 14a of the peak amplifier 14 and the enable terminal 15a of the peak amplifier 15.

The operation circuit 22 may output only one of the signal S2c and the signal S2d. That is, the operation circuit 22 may output the signal S2c to the enable terminal 14a of the peak amplifier 14 and need not output the signal S2d to the enable terminal 15a of the peak amplifier 15. Alternatively, the operation circuit 22 may output the signal S2d to the enable terminal 15a of the peak amplifier 15 and need not output the signal S2c to the enable terminal 14a of the peak amplifier 14.

The signal S2a can be input to the bias circuit 19 from the operation circuit 22. When the signal S2a is input, the bias circuit 19 applies the bias based on the signal S2a to the peak amplifier 14. When the signal S2a is not input, the bias circuit 19 applies a predetermined bias to the peak amplifier 14.

The collector or drain of the amplifying transistor (to be described later) in the peak amplifier 14 is electrically connected to the power supply potential Vcc with a choke coil L3 interposed therebetween. A supply current I_{PD} flows from the power supply potential Vcc to the collector of the amplifying transistor with the choke coil L3 interposed therebetween. The supply current I_{PD} is a collector current when the amplifying transistor in the peak amplifier 14 is a bipolar transistor, and is a drain current when the amplifying transistor in the peak amplifier 14 is a field effect transistor.

The peak amplifier 14 has an enable terminal 14a for controlling an operation state (high frequency signal amplification state) and a non-operation state (high frequency signal non-amplification state). The signal S2c can be input to the enable terminal 14a from the operation circuit 22. The peak amplifier 14 can be controlled to be in the operation state or the non-operation state depending on the signal S2c.

In the case of the operation state, the peak amplifier 14 outputs the high frequency signal RF22, which is amplified from the high frequency signal RF21, to the peak amplifier 15 with a capacitor C3 interposed therebetween. The capacitor C3 is a DC cut capacitor that cuts a DC component of the high frequency signal RF22. The peak amplifier 14 does not amplify the high frequency signal RF21 in the non-operation state.

The signal S2b can be input to the bias circuit 20 from the operation circuit 22. When the signal S2b is input, the bias circuit 20 applies the bias based on the signal S2b to the peak amplifier 15. When the signal S2b is not input, the bias circuit 20 applies a predetermined bias to the peak amplifier 15.

The collector or drain of the amplifying transistor in the peak amplifier 15 is electrically connected to the power supply potential Vcc with a choke coil L4 interposed therebetween. A supply current I_{PF} flows from the power supply potential Vcc to the collector or drain of the amplifying transistor with the choke coil L4 interposed therebetween. The supply current I_{PF} is a collector current when the amplifying transistor in the peak amplifier 14 is a bipolar transistor, and is a drain current when the amplifying transistor in the peak amplifier 14 is a field effect transistor.

The peak amplifier 15 has an enable terminal 15a for controlling the operation state and the non-operation state. The signal S2d can be input to the enable terminal 15a from the operation circuit 22. The peak amplifier 15 can be controlled to be in the operation state or the non-operation state depending on the signal S2d.

In the case of the operation state, the peak amplifier 15 outputs the high frequency signal RF23, which is amplified from the high frequency signal RF22, to the synthesizer 16 with a capacitor C4 interposed therebetween. The capacitor C4 is a DC cut capacitor that cuts a DC component of the high frequency signal RF23. The peak amplifier 15 does not amplify the high frequency signal RF22 in the non-operation state.

When the peak amplifier 14 and the peak amplifier 15 are in the non-operation state, the synthesizer 16 outputs the high frequency signal RF3 as the high frequency signal RFout. When the peak amplifier 14 and the peak amplifier 15 are in the operation state, the synthesizer 16 couples and synthesizes the high frequency signal RF13 and the high frequency signal RF23, and outputs the high frequency signal RFout.

### Effects

The supply current I_{CD} of the carrier amplifier 12 is a current that changes depending on the intensity of the high frequency signal RF11 input to the carrier amplifier 12, and is a current in which the operation state of the carrier amplifier 12 is reflected. That is, the current monitoring circuit 21 operates in a feedforward manner depending on the high frequency signal RF11. Here, the high frequency signal RF11 is input to the carrier amplifier 12 earlier than the high frequency signal RF12 is input to the carrier amplifier 13. In other words, the operation state of the carrier amplifier 12 changes faster compared to the operation state of the carrier amplifier 13. Therefore, the Doherty amplifier circuit 1 can detect the intensity of the high frequency signal RF11 in which the operation state of the carrier amplifier 12 is reflected by monitoring the supply current I_{CD} of the carrier amplifier 12, and can predict the saturation of the carrier amplifier 13 before the carrier amplifier 13 actually saturates. As a result, the Doherty amplifier circuit 1 can rapidly activate the peak amplifier 14 and the peak amplifier 15 as compared to United States Patent Application, Publication No. 2016/0241209, United States Patent Application, Publication No. 2020/0028472, and Japanese Unexamined Patent Application Publication No. 2019-041277. Accordingly, the Doherty amplifier circuit 1 can suppress a decrease in quality of the high frequency signal RFout.

### First Specific Example of Circuit Configuration of Current Monitoring Circuit and Operation Circuit

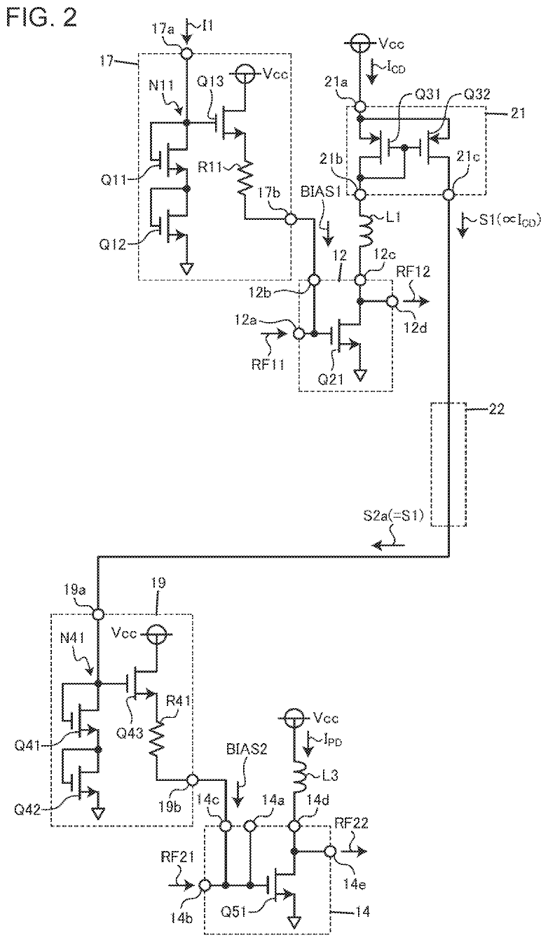

FIG. 2 is a diagram showing a first specific example of a circuit configuration of a current monitoring circuit and an operation circuit of the Doherty amplifier circuit of the first embodiment.

In the example shown in FIG. 2, the signal S2a is input to a terminal 19a of the bias circuit 19, and the signal S2c is not input to the enable terminal 14a of the peak amplifier 14.

In FIG. 2, the circuit configuration of the bias circuit 17 is shown, but the circuit configuration of the bias circuit 18 is the same as the circuit configuration of the bias circuit 17, so that the illustration and description are omitted. In addition, in FIG. 2, the circuit configuration of the carrier amplifier 12 is shown, but the circuit configuration of the carrier amplifier 13 is also the same as the circuit configuration of the carrier amplifier 12, so that the illustration and description are omitted. In FIG. 2, the circuit configuration of the bias circuit 19 is shown, but the circuit configuration of the bias circuit 20 is the same as the circuit configuration of the bias circuit 19, so that the illustration and description are omitted. In FIG. 2, the circuit configuration of the peak amplifier 14 is shown, but the circuit configuration of the peak amplifier 15 is the same as the circuit configuration of the peak amplifier 14, so that the illustration and description are omitted.

The bias circuit 17 includes N-channel transistors Q11, Q12, and Q13, and a resistor R11.

Each transistor is a field effect transistor, but the present disclosure is not limited thereto. The transistor may be, for example, a bipolar transistor. Examples of the bipolar transistor include a heterojunction bipolar transistor (HBT), but the present disclosure is not limited thereto. The transistor may be a multi-finger transistor in which a plurality of unit transistors are electrically connected in parallel. The unit transistor refers to the minimum configuration in which a transistor is configured.

When each transistor is a bipolar transistor, the emitter corresponds to the source of the FET, the base corresponds to the gate of the FET, and the collector corresponds to the drain of the FET.

A setting current I1 is input to a terminal 17a of the bias circuit 17.

The gate and the drain of the transistor Q11 are electrically connected to the terminal 17a with a node N11 interposed therebetween. That is, the transistor Q11 is diode-connected.

The gate and the drain of the transistor Q12 are electrically connected to the source of the transistor Q11. That is, the transistor Q12 is diode-connected. The source of the transistor Q12 is electrically connected to the reference potential. The reference potential is exemplified by the ground potential, but the present disclosure is not limited thereto.

The transistor Q11 and the transistor Q12 generate a voltage depending on the setting current I1. This voltage is the voltage at the node N11.

The drain of the transistor Q13 is electrically connected to the power supply potential Vcc. The gate of the transistor Q13 is electrically connected to the node N11. The source of the transistor Q13 is electrically connected to one end of the resistor R11. That is, the transistor Q13 and the resistor R11 are source follower-connected. The other end of the resistor R11 is electrically connected to a terminal 17b.

The transistor Q13 outputs a bias voltage or a bias current BIAS1 depending on the voltage of the node N11 from the terminal 17b with the resistor R11 interposed therebetween.

The carrier amplifier 12 includes a transistor Q21.

The high frequency signal RF11 is input to a terminal 12a of the carrier amplifier 12. The bias voltage or the bias current BIAS1 is input to a terminal 12b of the carrier amplifier 12. The supply current I_{Cd} is input to a terminal 12c of the carrier amplifier 12 from one end of the choke coil L1.

The gate of the transistor Q21 is electrically connected to the terminal 12a and the terminal 12b. The drain of the transistor Q21 is electrically connected to the terminal 12c and the terminal 12d. The source of the transistor Q21 is electrically connected to the reference potential.

The bias voltage or the bias current BIAS1 is input to the gate of the transistor Q21 from the terminal 12b. In addition, the high frequency signal RF11 is input to the gate of the transistor Q21 from the terminal 12a. The supply current I_{CD} is input to the drain of the transistor Q21 from the terminal 12c.

The transistor Q21 amplifies the high frequency signal RF11 and outputs the high frequency signal RF12 from the terminal 12d.

The current monitoring circuit 21 includes a P-channel transistor Q31 and a transistor Q32.

A terminal 21a of the current monitoring circuit 21 is electrically connected to the power supply potential Vcc. A terminal 21b of the current monitoring circuit 21 is electrically connected to the other end of the choke coil L1.

The source of the transistor Q31 is electrically connected to the terminal 21a. The gate and the drain of the transistor Q31 are electrically connected to the terminal 21b. That is, the transistor Q31 is diode-connected. The supply current I_{CD} of the transistor Q21 flows through the source-drain path of the transistor Q31.

The source of the transistor Q32 is electrically connected to the source of the transistor Q31. The gate of the transistor Q32 is electrically connected to the gate of the transistor Q31. That is, the transistor Q31 and the transistor Q32 are current-mirror connected. The drain of the transistor Q32 is electrically connected to a terminal 21c.

The transistor Q32 outputs a current proportional to the supply current I_{CD} from the terminal 21c as the signal S1. That is, the current value of the signal S1 is proportional to the current value of the supply current I_{CD}.

As shown in FIG. 2, when the signal S2a is input to the bias circuit 19, the operation circuit 22 is optional. In this case, the signal S2a is the signal S1. That is, the current value of the signal S2a is the same as the current value of the signal S1 (the current value depending on the current value of the supply current I_{CD}).

The bias circuit 19 includes N-channel transistors Q41, Q42, and Q43, and a resistor R41.

The signal S2a is input to a terminal 19a of the bias circuit 19.

The connection relationship of the transistor Q41, the transistor Q42, the transistor Q43, the resistor R41, and a node N41 is the same as the connection relationship of the transistor Q11, the transistor Q12, the transistor Q13, the resistor R11, and the node N11, and thus the description thereof will be omitted.

The transistor Q43 outputs a bias voltage or a bias current BIAS2 depending on the voltage of the node N41 from the terminal 19b with the resistor R41 interposed therebetween.

The peak amplifier 14 includes a transistor Q51.

In the first specific example, no signal is input to the enable terminal 14a of the peak amplifier 14. The high frequency signal RF21 is input to a terminal 14b of the peak amplifier 14. The bias voltage or the bias current BIAS2 is input to a terminal 14c of the peak amplifier 14. The supply current I_{PD} is input to a terminal 14d of the peak amplifier 14 from one end of the choke coil L3.

The gate of the transistor Q51 is electrically connected to the enable terminal 14a, the terminal 14b, and the terminal 14c. The drain of the transistor Q51 is electrically connected to the terminal 14d and the terminal 14e. The source of the transistor Q51 is electrically connected to the reference potential. The enable terminal 14a may be omitted.

The bias voltage or the bias current BIAS2 is input to the gate of the transistor Q51 from the terminal 14c. In addition, the high frequency signal RF21 is input to the gate of the transistor Q51 from the terminal 14b. The supply current I_{PD} is input to the drain of the transistor Q51 from the terminal 14d.

The transistor Q51 amplifies the high frequency signal RF21 and outputs the high frequency signal RF22 from the terminal 14e.

The operations of the carrier amplifier 12, the current monitoring circuit 21, the bias circuit 19, and the peak amplifier 14 will be described.

When the intensity of the high frequency signal RF11 input to the carrier amplifier 12 is high and the power input to the carrier amplifier 12 is large, the supply current I_{CD} increases. Accordingly, the current monitoring circuit 21 increases the signal S1 (=signal S2a). Therefore, the bias circuit 19 increases the bias voltage or the bias current BIAS2. Accordingly, the peak amplifier 14 performs an amplification operation.

When the intensity of the high frequency signal RF11 input to the carrier amplifier 12 is low and the power input to the carrier amplifier 12 is small, the supply current I_{CD} decreases. Accordingly, the current monitoring circuit 21 decreases the signal S1 (=signal S2a). Therefore, the bias circuit 19 decreases the bias voltage or the bias current BIAS2. Accordingly, the peak amplifier 14 does not perform an amplification operation.

### Effect of First Specific Example of Circuit Configuration of Current Monitoring Circuit and Operation Circuit

For example, as a method of detecting the power input to the carrier amplifier 12, it is also conceivable to detect the high frequency signal RF11 using a detector circuit. However, the detector circuit has a large amount of hardware. On the other hand, the current monitoring circuit 21 can be configured, for example, using a current mirror circuit (two transistors) as an example. That is, the current monitoring circuit 21 can reduce the amount of hardware as compared to the detector circuit. Therefore, the Doherty amplifier circuit 1 can be reduced in size and reduced in cost as compared to a case where the detector circuit is used.

### Second Specific Example of Circuit Configuration of Current Monitoring Circuit and Operation Circuit

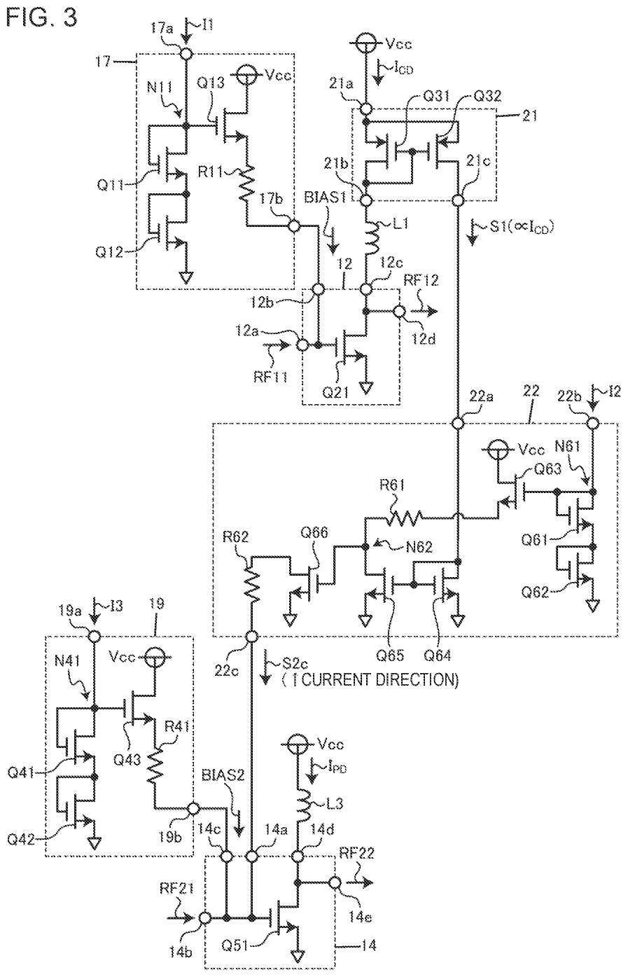

FIG. 3 is a diagram showing a second specific example of a circuit configuration of a current monitoring circuit and an operation circuit of the Doherty amplifier circuit of the first embodiment.

In the example shown in FIG. 3, the signal S2c is input to the enable terminal 14a of the peak amplifier 14, and the signal S2a is not input to the terminal 19a of the bias circuit 19. A setting current I3 is input to the terminal 19a of the bias circuit 19 instead of the signal S2a.

In the present example, the operation circuit 22 is an inverting amplifier circuit, but the present disclosure is not limited thereto.

The operation circuit 22 includes transistors Q61 to Q66, and resistors R61 and R62.

The signal S1 (∝ supply current I_{CD}) is input to a terminal 22a of the operation circuit 22. A setting current I2 is input to a terminal 22b of the operation circuit 22.

The gate and the drain of the transistor Q61 are electrically connected to the terminal 22b with a node N61 interposed therebetween. That is, the transistor Q61 is diode-connected.

The gate and the drain of the transistor Q62 are electrically connected to the source of the transistor Q61. That is, the transistor Q62 is diode-connected. The source of the transistor Q62 is electrically connected to the reference potential.

The transistor Q61 and the transistor Q62 generate a voltage depending on the setting current I2. This voltage is the voltage at the node N61.

The drain of the transistor Q63 is electrically connected to the power supply potential Vcc. The gate of the transistor Q63 is electrically connected to the node N61. The source of the transistor Q63 is electrically connected to one end of the resistor R61. That is, the transistor Q63 and the resistor R61 are source follower-connected. The other end of the resistor R61 is electrically connected to a node N62.

The transistor Q63 may output a current depending on the voltage of the node N61 to the node N62.

The drain and the gate of the transistor Q64 are electrically connected to the terminal 22a. That is, the transistor Q64 is diode-connected. The source of the transistor Q64 is electrically connected to the reference potential. The signal S1 (∝ supply current I_{CD}) flows through the drain-source path of the transistor Q64.

The source of the transistor Q65 is electrically connected to the reference potential. The gate of the transistor Q65 is electrically connected to the drain and the gate of the transistor Q64. That is, the transistor Q64 and the transistor Q65 are current-mirror connected. The drain of the transistor Q65 is electrically connected to the node N62.

The source of the transistor Q66 is electrically connected to the reference potential. The gate of the transistor Q66 is electrically connected to the node N62. The drain of the transistor Q66 is electrically connected to one end of the resistor R62. The other end of the resistor R62 is electrically connected to a terminal 22c. The transistor Q66 causes a current depending on the voltage of the node N62 to flow from the terminal 22c toward the reference potential.

The terminal 22c is electrically connected to the enable terminal 14a of the peak amplifier 14. The operation circuit 22 draws a current from the enable terminal 14a of the peak amplifier 14 depending on the signal S1. That is, the signal S2c is a current in a direction from the enable terminal 14a of the peak amplifier 14 to the terminal 22c.

The operation of the operation circuit 22 will be described.

When the intensity of the high frequency signal RF11 input to the carrier amplifier 12 is high and the power input to the carrier amplifier 12 is high, the supply current I_{CD} increases. Accordingly, the current monitoring circuit 21 increases the signal S1. When the signal S1 increases, the gate potential of the transistor Q64 rises, the gate voltage of the transistor Q65 also rises, and the current flowing through the path from the source of the transistor Q63, through the resistor R61, to the node N62, then to the drain of the transistor Q65, and further to the source of the transistor Q65, and to the reference potential, increases. Then, the voltage drop across the resistor R61 increases, so that the voltage of the node N62 decreases. As a result, the gate voltage of the transistor Q66 decreases, and thus the transistor Q66 enters the off state. Therefore, the current (signal S2c) flowing through the path from the enable terminal 14a of the peak amplifier 14, to the terminal 22c of the operation circuit 22, through the resistor R62, to the drain of the transistor Q66, and further to the source of the transistor Q66, and to the reference potential, decreases. That is, the current flowing from the terminal 14c of the peak amplifier 14 to the enable terminal 14a of the peak amplifier 14 decreases, and the bias applied to the transistor Q51 increases. Accordingly, the peak amplifier 14 performs an amplification operation.

When the intensity of the high frequency signal RF11 input to the carrier amplifier 12 is low and the power input to the carrier amplifier 12 is small, the supply current I_{CD} decreases. Accordingly, the current monitoring circuit 21 decreases the signal S1. When the signal S1 decreases, the gate potential of the transistor Q64 decreases, the gate voltage of the transistor Q65 also decreases, and the current flowing through the path from the source of the transistor Q63, through the resistor R61, to the node N62, then to the drain of the transistor Q65, and further to the source of the transistor Q65, and to the reference potential, decreases. Then, the voltage drop across the resistor R61 decreases, so that the voltage of the node N62 rises. As a result, the gate voltage of the transistor Q66 rises, and thus the transistor Q66 enters the on state. Therefore, the current (signal S2c) flowing through the path from the enable terminal 14a of the peak amplifier 14, to the terminal 22c of the operation circuit 22, through the resistor R62, to the drain of the transistor Q66, and further to the source of the transistor Q66, and to the reference potential, increases That is, the current flowing from the terminal 14c of the peak amplifier 14 to the enable terminal 14a of the peak amplifier 14 increases, and the bias applied to the transistor Q51 decreases. Accordingly, the peak amplifier 14 does not perform an amplification operation.

### Effect of Second Specific Example of Circuit Configuration of Current Monitoring Circuit and Operation Circuit

In the first specific example, the signal S2a is input to the bias circuit 19, and the bias circuit 19 outputs the bias voltage or the bias current BIAS2 based on the signal S2a. Therefore, in the first specific example, it is difficult to set the bias of the peak amplifier 14 at the time of idling to a desired value.

On the other hand, in the second specific example, since the signal S2c is input to the enable terminal 14a of the peak amplifier 14, the bias voltage or the bias current BIAS2, and the signal S2c can be controlled separately. Accordingly, in the second specific example, it is easy to set the bias of the peak amplifier 14 at the time of idling to a desired value.

### Second Embodiment

### Overall Configuration

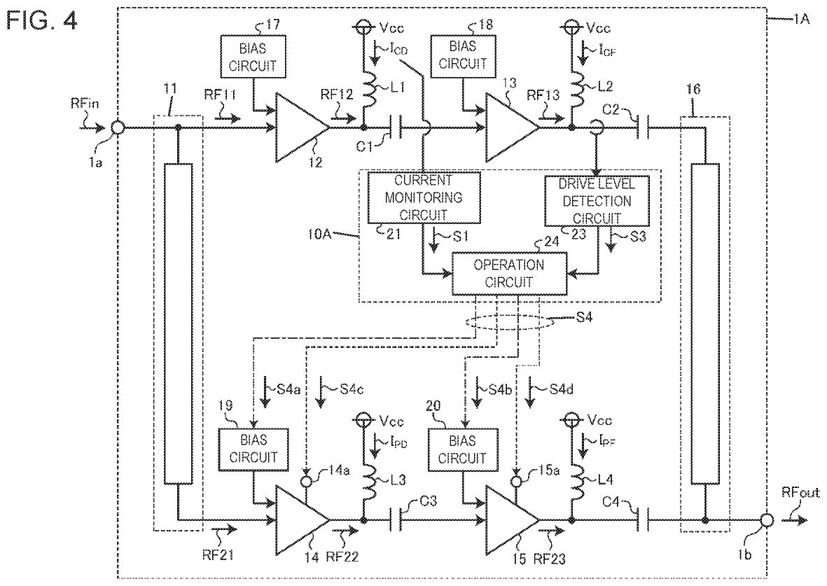

FIG. 4 is a diagram showing a configuration of a Doherty amplifier circuit of a second embodiment.

A Doherty amplifier circuit 1A includes a control circuit 10A instead of the control circuit 10, as compared to the Doherty amplifier circuit 1 (refer to FIG. 1). The control circuit 10A further includes a drive level detection circuit 23 as compared to the control circuit 10. In addition, the control circuit 10A includes an operation circuit 24 instead of the operation circuit 22, as compared to the control circuit 10.

The drive level detection circuit 23 detects a drive level (operation level) of the carrier amplifier 13 based on the high frequency signal RF13, and outputs a signal S3 representing the drive level of the carrier amplifier 13 to the operation circuit 24. The signal S3 may be a signal (inversion signal) that changes complementarily to the drive level of the carrier amplifier 13.

The operation circuit 24 adds an operation to the signal S1 and the signal S3 and outputs a signal S4. The operation circuit 24 is exemplified to add the signal S1 and the signal S3. However, the present disclosure is not limited thereto. The signal S4 is exemplified to include signals S4a, S4b, S4c, and S4d.

As a first specific example (to be described later), the operation circuit 24 outputs the signal S4a to the bias circuit 19 and outputs the signal S4b to the bias circuit 20. When outputting a current signal, the operation circuit 24 may respectively output separate signal S4a and signal S4b to the bias circuit 19 and the bias circuit 20, as shown in FIG. 4. When outputting a voltage signal, the operation circuit 24 may output one common signal S4 to the bias circuit 19 and the bias circuit 20.

The operation circuit 24 may output only one of the signal S4a and the signal S4b. That is, the operation circuit 24 may output the signal S4a to the bias circuit 19 and need not output the signal S4b to the bias circuit 20. Alternatively, the operation circuit 22 may output the signal S4b to the bias circuit 20 and need not output the signal S4a to the bias circuit 19.

As a second specific example (to be described later), the operation circuit 24 outputs a signal S4c to the enable terminal 14a (to be described later) of the peak amplifier 14 and outputs a signal S4d to the enable terminal 15a of the peak amplifier 15. When outputting a current signal, the operation circuit 24 may respectively output separate signal S4c and signal S4d to the enable terminal 14a of the peak amplifier 14 and the enable terminal 15a of the peak amplifier 15, as shown in FIG. 4. When outputting a voltage signal, the operation circuit 24 may output one common signal S4 to the enable terminal 14a of the peak amplifier 14 and the enable terminal 15a of the peak amplifier 15.

The operation circuit 24 may output only one of the signal S4c and the signal S4d. That is, the operation circuit 24 may output the signal S4c to the enable terminal 14a of the peak amplifier 14 and need not output the signal S4d to the enable terminal 15a of the peak amplifier 15. Alternatively, the operation circuit 24 may output the signal S4d to the enable terminal 15a of the peak amplifier 15 and need not output the signal S4c to the enable terminal 14a of the peak amplifier 14.

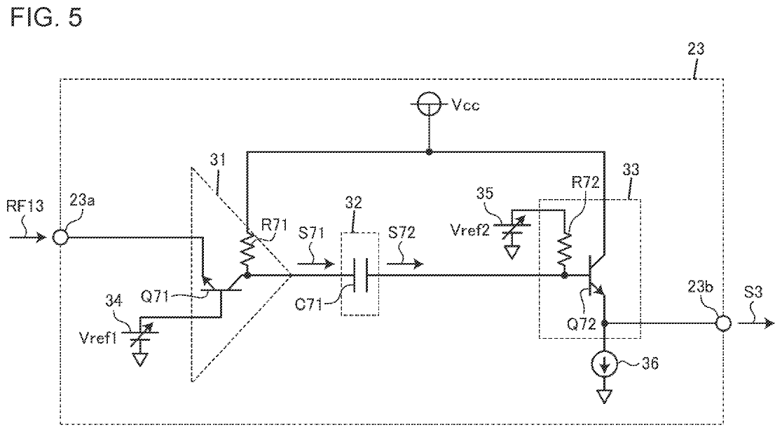

FIG. 5 is a diagram showing a configuration of a drive level detection circuit of the Doherty amplifier circuit of the second embodiment.

The high frequency signal RF13 is input to a terminal 23a of the drive level detection circuit 23. The drive level detection circuit 23 outputs the signal S3 from a terminal 23b.

The drive level detection circuit 23 includes a comparator circuit 31, a DC cut circuit 32, a detection circuit 33, a voltage source 34 and 35, and a current source 36.

The comparator circuit 31 outputs a signal S71 depending on the voltage of the high frequency signal RF13 with a voltage Vref1 output from the voltage source 34 as a boundary.

The comparator circuit 31 includes a transistor Q71 and a resistor R71.

The emitter of the transistor Q71 is electrically connected to the terminal 23a. The base of the transistor Q71 is electrically connected to the high voltage side end of the voltage source 34, and the voltage Vref1 is input. The collector of the transistor Q71 is electrically connected to the power supply potential Vcc with the resistor R71 interposed therebetween. In addition, the collector of the transistor Q71 is electrically connected to one end of the DC cut circuit 32.

The transistor Q71, with the voltage Vref1 input to the base as a reference voltage, enters the on state when the voltage of the high frequency signal RF13 input to the emitter is low, and enters the off state when the voltage of the high frequency signal RF13 input to the emitter is high. When the transistor Q71 is in the on state, a voltage drop occurs across the resistor R71, and thus the signal S71 is at a low level. When the transistor Q71 is in the off state, a voltage drop does not occur across the resistor R71, and thus the signal S71 is at a high level.

The DC cut circuit 32 cuts a DC component of the signal S71. That is, the DC cut circuit 32 allows high frequency components of the signal S71 to pass therethrough.

The DC cut circuit 32 includes a capacitor C71. One end of the capacitor C71 is electrically connected to the comparator circuit 31. The other end of the capacitor C71 is electrically connected to the detection circuit 33.

The capacitor C71 is a DC cut capacitor that cuts the DC component of the signal S71 output from the comparator circuit 31 and outputs a signal S72 to the detection circuit 33.

As described above, by cutting the DC component included in the signal S71, the drive level detection circuit 23 can suppress a delay in the response time of the comparator circuit 31 caused by the DC component. In addition, by cutting the DC component included in the signal S71, the drive level detection circuit 23 can suppress the fluctuation of the bias point of the detection circuit 33.

That is, the drive level detection circuit 23 has a configuration to cut the DC component included in the signal S71, so that the signal S71 does not act on the operation of the comparator circuit 31. As a result, the drive level detection circuit 23 has a remarkable effect that the delay in the response time of the comparator circuit 31 can be suppressed.

The detection circuit 33 detects a signal S72 from which the DC component included in the signal S71 is removed by the DC cut circuit 32. The detection circuit 33 converts the signal S72 into a DC component and outputs the signal S3.

The detection circuit 33 includes a transistor Q72 and a resistor R72.

The collector of the transistor Q72 is electrically connected to the power supply potential Vcc. The base of the transistor Q72 is electrically connected to the other end of the capacitor C71. In addition, the base of the transistor Q72 is electrically connected to the high voltage side end of the voltage source 35 with the resistor R72 interposed therebetween, and a voltage Vref2 is input. The emitter of the transistor Q72 is electrically connected to the current source 36.

The transistor Q72 and the current source 36 are emitter-follower-connected. The transistor Q72 adjusts the conduction angle by the voltage Vref2, and smoothes high frequency components of the signal S72 into direct current using a capacitor (not shown).

The transistor Q72 enters the on state when the signal S72 is at a high level, and outputs a current from the emitter to the current source 36. Therefore, the drive level detection circuit 23 outputs a signal S3 close to OA.

The transistor Q72 enters the off state when the signal S72 is at a low level, and does not output a current from the emitter to the current source 36. Therefore, the drive level detection circuit 23 outputs a signal S3 in the negative direction (draws the current).

The signal S71 includes a DC component that requires time to stabilize due to the influence of the operation of the comparator circuit 31. The DC cut circuit 32 cuts the DC component included in the signal S71. The DC cut circuit 32 outputs the signal S72, which is used as the detection signal, to the detection circuit 33. That is, the DC cut circuit 32 isolates the comparator circuit 31 and the detection circuit 33 in a DC manner so that the DC component included in the signal S71 does not act on the detection circuit 33. As described above, the drive level detection circuit 23 cuts the DC component included in the signal S71 and uses the signal S72, which is a high frequency component included in the signal S71, as the detection signal.

Accordingly, the drive level detection circuit 23 can suppress the response delay that occurs when the signal S71 including the DC component is used as the detection signal.

Next, an outline of the operation of the drive level detection circuit 23 will be described.

The terminal 23a of the drive level detection circuit 23 is electrically connected to the output terminal of the carrier amplifier 13 (the collector of the emitter-grounded amplifying transistor). In this case, the instantaneous minimum voltage of the collector of the amplifying transistor in the carrier amplifier 13 decreases (approaches 0 V) as the carrier amplifier 13 approaches saturation. That is, the drive level detection circuit 23 enters a conductive state in a period in which the voltage (signal level) of the high frequency signal RF13 is lower than the voltage Vref1.

Here, the period of the conductive state is expressed as an angle range, and it is referred to as a conduction angle. The conduction angle increases as the high frequency signal RF13 increases. As the conduction angle increases, the DC component of the signal S71 output from the comparator circuit 31 also increases. The drive level detection circuit 23 cuts the DC component by the DC cut circuit 32.

The drive level detection circuit 23 includes the detection circuit 33 for an emitter follower. As a result, the detection circuit 33 has a high input impedance, and thus an input current may be small. Since the input impedance of the detection circuit 33 is high, the high frequency signal RF13 acts as a signal for operating the emitter follower, but does not directly act on the DC component of the signal S3. That is, the drive level detection circuit 23 can suppress the AC interaction between the comparator circuit 31 and the detection circuit 33 (increase the AC input impedance) by using the detection circuit 33 as the emitter follower.

This means that even when the AC output impedance of the comparator circuit 31 is high, it is possible to suppress the AC interaction between the comparator circuit 31 and the detection circuit 33. For example, when the output impedance of the comparator circuit 31 in the AC is high and the input impedance of the detection circuit 33 in the AC is low, when the detection circuit 33 starts to operate, the input impedance of the comparator circuit 31 usually decreases. That is, the AC output of the comparator circuit 31 usually becomes unstable. However, in the drive level detection circuit 23, since the detection circuit 33 is the emitter follower having a high input impedance, the AC output of the comparator circuit 31 is stable.

In FIG. 5, the comparator circuit 31 is described as being configured with a transistor with the base grounded. However, the present disclosure is not limited thereto. For example, the comparator circuit 31 may be configured with a transistor with the emitter grounded. That is, the comparator circuit 31 may be a comparator that compares the relationship between the voltage of the collector of the transistor and the voltage of the base.

Specifically, the comparator circuit 31 can implement the function of the comparator by using a phenomenon in which the base current increases when the potential of the collector is lower than the base potential by the voltage V_{BE} between the base and the emitter. That is, the comparator circuit 31 may be configured to bias the base of the transistor with the voltage V_{BE} between the base and the emitter, causing the base current to flow when the potential of the collector approaches “0”.

In this case, the emitter of the transistor of the comparator circuit 31 is electrically connected to the reference potential (ground potential). In addition, the collector of the transistor of the comparator circuit 31 is electrically connected to the output terminal (the collector of the amplifying transistor) of the carrier amplifier 13. In addition, the base of the transistor of the comparator circuit 31 is electrically connected to one end of the DC cut circuit 32 while the voltage Vref1 is input.

As described above, by using the transistor with the emitter grounded in the comparator circuit 31, it is possible to reduce the failure of the transistor as compared to the case of using the transistor with the base grounded. This is because, when the transistor with the base grounded is used, a large voltage is applied between the base and the emitter, and when the transistor with the emitter grounded is used, a large voltage is not applied between the base and the emitter.

### Effects

The supply current I_{CD} of the carrier amplifier 12 is a current that changes depending on the intensity of the high frequency signal RF11 input to the carrier amplifier 12, and is a current in which the operation state of the carrier amplifier 12 is reflected. Here, the high frequency signal RF11 is input to the carrier amplifier 12 earlier than the high frequency signal RF13 is input to the carrier amplifier 13. In other words, the operation state of the carrier amplifier 12 changes faster compared to the operation state of the carrier amplifier 13. Therefore, the Doherty amplifier circuit 1A can detect the intensity of the high frequency signal RF11 in which the operation state of the carrier amplifier 12 is reflected by monitoring the supply current I_{CD} of the carrier amplifier 12, and can predict the saturation of the carrier amplifier 13 before the carrier amplifier 13 actually saturates. As a result, the Doherty amplifier circuit 1 can rapidly activate the peak amplifier 14 and the peak amplifier 15 as compared to United States Patent Application, Publication No. 2016/0241209, United States Patent Application, Publication No. 2020/0028472, and Japanese Unexamined Patent Application Publication No. 2019-041277. Accordingly, the Doherty amplifier circuit 1A can suppress a decrease in quality of the high frequency signal RFout.

In addition, when the temperature and other peripheral environments change (for example, when the gain of the carrier amplifiers 12 and 13 increases at an extremely low temperature), the carrier amplifiers 12 and 13 may saturate even when the power of the high frequency signal RF11 is small. The Doherty amplifier circuit 1A detects the drive level of the carrier amplifier 13 to be able to cope with such a case. When the carrier amplifier 13 is close to saturation, the Doherty amplifier circuit 1A immediately activates the peak amplifiers 14 and 15, even when the power of the high frequency signal RF11 is small.

Since the Doherty amplifier circuit 1A monitors the supply current I_{CD}, even if it takes time to detect the drive level of the carrier amplifier 13, the peak amplifiers 14 and 15 can be activated without necessarily saturating the carrier amplifiers 12 and 13. Accordingly, the Doherty amplifier circuit 1A can suppress a decrease in quality of the high frequency signal RFout.

The Doherty amplifier circuit 1A can be considered to operate in a feedforward manner depending on the input signal intensity (supply current I_{CD}) of the carrier amplifier 12 and operate in a feedback manner depending on the drive level of the carrier amplifier 13.

### First Specific Example of Operation Circuit

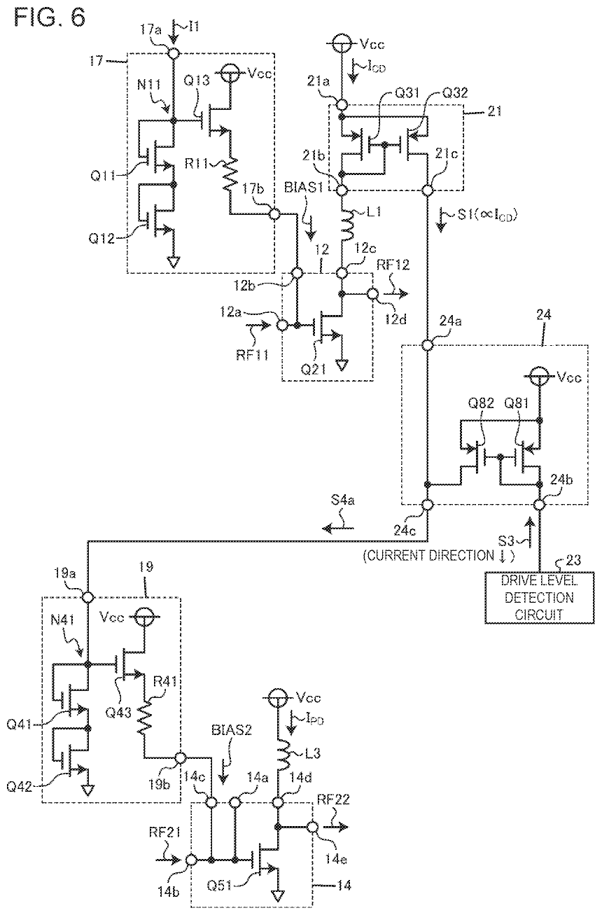

FIG. 6 is a diagram showing a first specific example of a circuit configuration of an operation circuit of the Doherty amplifier circuit of the second embodiment.

In the example shown in FIG. 6, the signal S4a is input to the terminal 19a of the bias circuit 19, and the signal S4c is not input to the enable terminal 14a of the peak amplifier 14.

The operation circuit 24 includes a P-channel transistor Q81 and a transistor Q82.

A terminal 24a of the operation circuit 24 is electrically connected to the terminal 21c of the current monitoring circuit 21, and the signal S1 is input. A terminal 24b of the operation circuit 24 is electrically connected to the drive level detection circuit 23, and the signal S3 is input (the current is drawn). The terminal 24c of the operation circuit 24 is electrically connected to the terminal 24a.

The source of the transistor Q81 is electrically connected to the power supply potential Vcc. The gate and the drain of the transistor Q81 are electrically connected to the terminal 24b. That is, the transistor Q81 is diode-connected. The signal S3 (drawn current) flows through the source-drain path of the transistor Q81.

The source of the transistor Q82 is electrically connected to the source of the transistor Q81. The gate of the transistor Q82 is electrically connected to the gate of the transistor Q81. That is, the transistor Q81 and the transistor Q82 are current-mirror connected. The drain of the transistor Q82 is electrically connected to the terminal 24c.

The transistor Q82 outputs a current proportional to the signal S3 (drawn current) to the terminal 24c. Therefore, the signal S4 output from the terminal 24c by the operation circuit 24 is the sum of the current proportional to the signal S1 (∝I_{CD}) and the signal S3 (drawn current). The signal S4 is input to the terminal 19a of the bias circuit 19.

### Effect of First Specific Example of Operation Circuit

The operation circuit 24 can implement a circuit that operates in a feedforward manner depending on the supply current I_{CD} and operates in a feedback manner depending on the drive level of the carrier amplifier 13.

### Second Specific Example of Operation Circuit

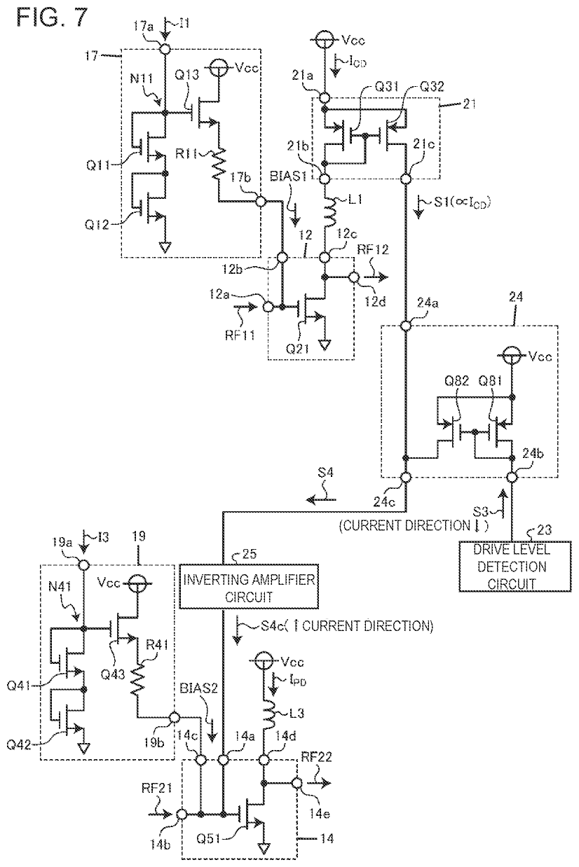

FIG. 7 is a diagram showing a second specific example of a circuit configuration of an operation circuit of the Doherty amplifier circuit of the second embodiment.

In the example shown in FIG. 7, the signal S4c is input to the enable terminal 14a of the peak amplifier 14, and the signal S4a is not input to the terminal 19a of the bias circuit 19. A setting current I3 is input to the terminal 19a of the bias circuit 19 instead of the signal S4a.

FIG. 7 is a diagram showing a second specific example of a circuit configuration of an operation circuit of the Doherty amplifier circuit of the second embodiment.

In the second specific example, the signal S4 is input to the inverting amplifier circuit 25. The inverting amplifier circuit 25 inverts and amplifies the signal S4 to output the signal S4c to the enable terminal 14a of the peak amplifier 14. The circuit configuration of the inverting amplifier circuit 25 is exemplified by the same circuit configuration as the operation circuit 22 (refer to FIG. 3), but the present disclosure is not limited thereto.

### Effect of Second Specific Example of Operation Circuit

In the first specific example, the signal S4a is input to the bias circuit 19, and the bias circuit 19 outputs the bias voltage or the bias current BIAS2 based on the signal S4a. Therefore, in the first specific example, it is difficult to set the bias of the peak amplifier 14 at the time of idling to a desired value.

On the other hand, in the second specific example, since the signal S4c is input to the enable terminal 14a of the peak amplifier 14, the bias voltage or the bias current BIAS2, and the signal S4c can be controlled separately. Accordingly, in the second specific example, it is easy to set the bias of the peak amplifier 14 at the time of idling to a desired value.

### Configuration Example of Present Disclosure

The present disclosure can also have the following configuration.

(1) A Doherty amplifier circuit including:
a carrier amplifier that amplifies a high frequency signal;
a peak amplifier that amplifies the high frequency signal; and
a control circuit that controls the peak amplifier based on a supply current of an amplifying transistor in the carrier amplifier.

(2) The Doherty amplifier circuit according to the above (1), further including:
a bias circuit that biases the peak amplifier,
in which the control circuit controls the bias circuit based on the supply current.

(3) The Doherty amplifier circuit according to the above (1),
in which the peak amplifier includes a control terminal for controlling an operation state of the peak amplifier, and
the control circuit outputs a signal to the control terminal based on the supply current.

(4) The Doherty amplifier circuit according to any one of the above (1) to (3),
In which the control circuit controls the peak amplifier based on the supply current and a drive level of the carrier amplifier.

(5) The Doherty amplifier circuit according to any one of the above (1) to (4),
in which multi-stage carrier amplifiers are provided, and
the control circuit controls the peak amplifier based on the supply current of the amplifying transistor in a first stage carrier amplifier among the multi-stage carrier amplifiers.

(6) The Doherty amplifier circuit according to any one of the above (1) to (5),
in which multi-stage peak amplifiers are provided, and
the control circuit controls a final stage peak amplifier among the multi-stage peak amplifiers.

(7) The Doherty amplifier circuit according to the above (6),
in which the control circuit controls a first stage peak amplifier among the multi-stage peak amplifiers.

The above-described embodiment is for facilitating the understanding of the present disclosure, and is not intended to limit or interpret the present disclosure. The present disclosure can be modified or improved without necessarily departing from the spirit of the present disclosure, and the present disclosure also includes equivalents thereof.

What is claimed is:

1. A Doherty amplifier circuit comprising:
a carrier amplifier configured to amplify a high frequency signal;
a peak amplifier configured to amplify the high frequency signal; and
a control circuit configured to control the peak amplifier based on a supply current of an amplifying transistor in the carrier amplifier.

2. The Doherty amplifier circuit according to claim 1, further comprising:
a bias circuit configured to bias the peak amplifier,
wherein the control circuit is configured to control the bias circuit based on the supply current.

3. The Doherty amplifier circuit according to claim 1,
wherein the peak amplifier comprises a control terminal for controlling an operation state of the peak amplifier, and
wherein the control circuit is configured to output a signal to the control terminal based on the supply current.

4. The Doherty amplifier circuit according to claim 1, wherein the control circuit is configured to control the peak amplifier based on the supply current and based on a drive level of the carrier amplifier.

5. The Doherty amplifier circuit according to claim 1, comprising multiple stages of carrier amplifiers,
wherein the amplifier transistor is in a first stage carrier amplifier among the multiple stages of carrier amplifiers, and
wherein the control circuit is configured to control the peak amplifier based on the supply current of the amplifying transistor in the first stage carrier amplifier.

6. The Doherty amplifier circuit according to claim 1, comprising multiple stages of peak amplifiers,
wherein the control circuit is configured to control a final stage peak amplifier among the multiple stages of peak amplifiers.

7. The Doherty amplifier circuit according to claim 5, comprising multiple stages of peak amplifiers,
wherein the control circuit is configured to control a final stage peak amplifier among the multiple stages of peak amplifiers.

8. The Doherty amplifier circuit according to claim 6, wherein the control circuit is configured to control a first stage peak amplifier among the multiple stages of peak amplifiers.

9. The Doherty amplifier circuit according to claim 6, comprising multiple stages of peak amplifiers,
wherein the control circuit is configured to control a first stage peak amplifier among the multiple stages of peak amplifiers.
